(19) United States
(12) Patent Application Publication
(10) Pub. No.: US 2017/0213967 A1
(43) Pub. Date: Jul. 27, 2017

(54) PEROVSKITE LIGHT-EMITTING DEVICE AND FABRICATING METHOD THEREOF

(71) Applicant: National Chiao Tung University, Hsinchu City (TW)

(72) Inventors: Fang-Chung Chen, Nantou County (TW); Jiong-Fu Huang, Taichung City (TW)

(21) Appl. No.: 15/197,787

(22) Filed: Jun. 30, 2016

(30) Foreign Application Priority Data
Jan. 27, 2016 (TW) 105102493

(51) Int. Cl. H01L 51/00

(52) U.S. Cl. CPC H01L 51/006; H01L 51/0059; H01L 51/0061; H01L 51/0065; H01L 51/0047; H01L 51/0058; H01L 51/0077; H01L 51/5206

(57) ABSTRACT

A perovskite light-emitting device is provided. The perovskite light-emitting device includes a first electrode layer, a first charge injection layer, a first charge transport layer, a light-emitting layer, a second charge injection layer and a second electrode layer. The first charge injection layer is disposed on the first electrode layer. The first charge transport layer is disposed on the first charge injection layer, wherein the material of the first charge transport layer includes a crosslinkable material. The light-emitting layer is disposed on the first charge transport layer, wherein the material of the light-emitting layer includes a light-emitting material having a perovskite crystal structure. The second charge injection layer is disposed on the light-emitting layer. The second electrode layer is disposed on the second charge injection layer.

### CROSS-REFERENCE TO RELATED APPLICATION

This application claims the priority benefit of Taiwan application serial no. 105102493, filed on Jan. 27, 2016. The entirety of the above-mentioned patent application is hereby incorporated by reference herein and made a part of this specification.

### BACKGROUND OF THE INVENTION

Field of the Invention

The invention relates to a light-emitting device and a fabricating method thereof, and particularly relates to a perovskite light-emitting device and a fabricating method thereof.

Description of Related Art

Since the perovskite material is a good photoactive material, it is widely applied to the solar cells. In recent years, the perovskite material is further applied to light-emitting diodes. However, in the present perovskite light-emitting diodes, the hole injection energy barrier is too high, which often leads to low quantum efficiencies. Further, the perovskite material usually has the phenomenon of crystallization, thereby resulting in too many holes on the thin films thereof thus causing poor device efficiency. Therefore, how to overcome the existing problems of the perovskite light-emitting diode is one of the most eager research topics currently.

### SUMMARY OF THE INVENTION

The invention provides a perovskite light-emitting device and a fabricating method thereof. The perovskite light-emitting device exhibits high brightness, light-emitting efficiency, and device efficiency.

The invention provides a perovskite light-emitting device including a first electrode layer, a first charge injection layer, a first charge transport layer, a light-emitting layer, a second charge injection layer and a second electrode layer. The first charge injection layer is disposed on the first electrode layer. The first charge transport layer is disposed on the first charge injection layer, wherein the material of the first charge transport layer includes a crosslinkable material. The light-emitting layer is disposed on the first charge transport layer, wherein the material of the light-emitting layer includes a light-emitting material having a perovskite crystal structure. The second charge injection layer is disposed on the light-emitting layer. The second electrode layer is disposed on the second charge injection layer.

According to an embodiment of the invention, the light-emitting material having the perovskite crystal structure has a structure represented by the following formula (I):

ABX₃ (I)

wherein A is an organic ammonium cation; B is a group IV metal cation or a transition metal cation; X₃ are a combination of single type halogen-containing anion or a combination of multiple type halogen-containing anion.

According to an embodiment of the invention, the organic ammonium cation is a C₁ to C₅₀ alkyl ammonium cation or an aromatic ammonium cation; the group IV metal cation is Pb²⁺, Ge²⁺, or Sn²⁺; the transition metal cation is Cu²⁺, Ni²⁺, Co²⁺, Fe²⁺, Mn²⁺, or Eu²⁺; the single type halogen-containing anion is Cl⁻, Br⁻, or I⁻; the combination of multiple type halogen-containing anion has the following general formula: —Cl⁻ₓBr⁻_{y}I⁻_{z}, wherein x+y+z=3.

According to an embodiment of the invention, the light-emitting material having the perovskite crystal structure is CH₃NH₃PbBr₃, CH₃NH₃PbBr₂I, CH₃NH₃PbCl₃, or CH₃NH₃PbBrCl₂.

According to an embodiment of the invention, the first charge injection layer is an hole injection layer, the first charge transport layer is an hole transport layer, and the second charge injection layer is an electron injection layer, wherein the crosslinkable material includes a compound represented by the following formula 1, a compound represented by the following formula 2, or a compound represented by the following formula 3:

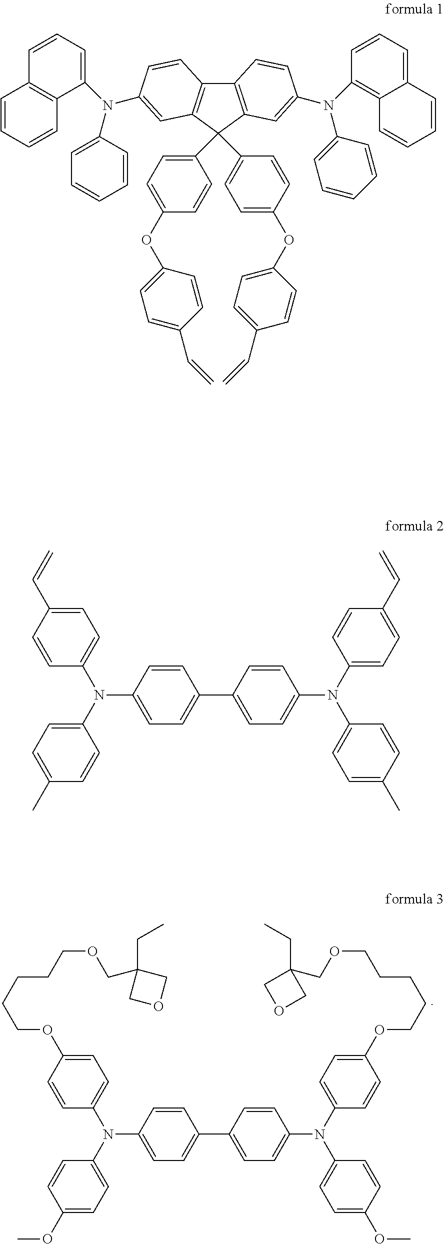 [SMILES: C=Cc1ccc(Oc2ccc(C3(c4ccc(Oc5ccc(C=C)cc5)cc4)c4cc(N(c5ccccc5)c5cccc6ccccc56)ccc4-c4ccc(N(c5ccccc5)c5cccc6ccccc56)cc43)cc2)cc1 ; C=Cc1ccc(N(c2ccc(C)cc2)c2ccc(-c3ccc(N(c4ccc(C)cc4)c4ccc(C=C)cc4)cc3)cc2)cc1 ; CCC1(COCCCCCOc2ccc(N(c3ccc(OC)cc3)c3ccc(-c4ccc(N(c5ccc(OC)cc5)c5ccc(OCCCCCOCC6(CC)COC6)cc5)cc4)cc3)cc2)COC1]

According to an embodiment of the invention, the first charge injection layer is an electron injection layer, the first charge transport layer is an electron transport layer, and the second charge injection layer is an hole injection layer, wherein the crosslinkable material includes a compound represented by the following formula 4, a compound represented by the following formula 5, or a compound represented by the following formula 6:

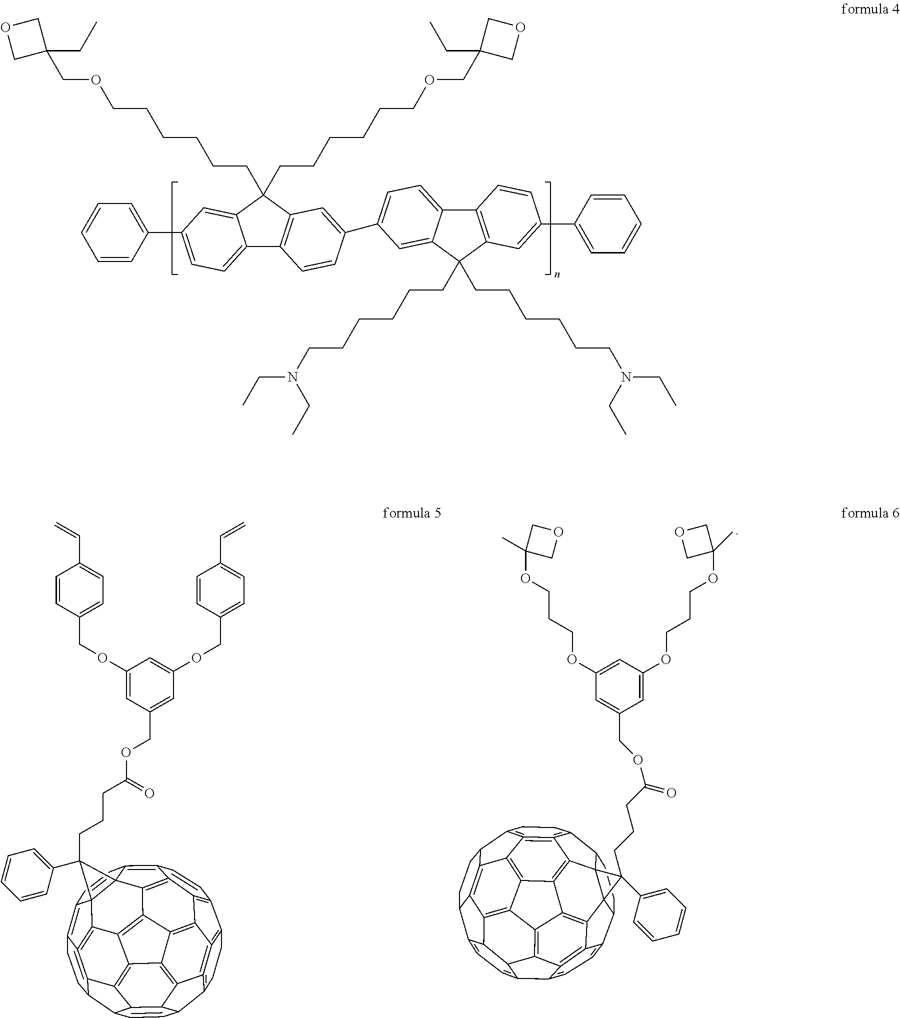

According to an embodiment of the invention, the perovskite light-emitting device further includes a second charge transport layer disposed between the light-emitting layer and the second charge injection layer.

The invention provides a fabricating method of a perovskite light-emitting device including the following steps. A first charge injection layer is formed on a first electrode layer. A first charge transport layer is formed on the first charge injection layer, wherein the material of the first charge transport layer includes a crosslinkable material. A light-emitting layer is formed on the first charge transport layer, wherein the material of the light-emitting layer includes a light-emitting material having a perovskite crystal structure. A second charge injection layer is formed on the light-emitting layer. A second electrode layer is formed on the second charge injection layer.

According to an embodiment of the invention, the light-emitting material having the perovskite crystal structure has a structure represented by the following formula (I):

ABX₃ (I)

wherein A is an organic ammonium cation; B is a group IV metal cation or a transition metal cation; X₃ are a combination of single type halogen-containing anion or a combination of multiple type halogen-containing anion.

According to an embodiment of the invention, the organic ammonium cation is a C₁ to C₅₀ alkyl ammonium cation or an aromatic ammonium cation; the group IV metal cation is Pb²⁺, Ge²⁺, or Sn²⁺; the transition metal cation is Cu²⁺, Ni²⁺, Co²⁺, Fe²⁺, Mn²⁺, or Eu²⁺; the single type halogen-containing anion is Cl⁻, Br⁻, or I⁻; the combination of multiple type halogen-containing anion has the following general formula: —Cl⁻ₓBr⁻_{y}I⁻_{z}, wherein x+y+z=3.

According to an embodiment of the invention, the light-emitting material having the perovskite crystal structure is CH₃NH₃PbBr₃, CH₃NH₃PbBr₂I, CH₃NH₃PbCl₃, or CH₃NH₃PbBrCl₂.

According to an embodiment of the invention, the first charge injection layer is an hole injection layer, the first charge transport layer is an hole transport layer, and the second charge injection layer is an electron injection layer, wherein the crosslinkable material includes a compound represented by the following formula 1, a compound represented by the following formula 2, or a compound represented by the following formula 3:

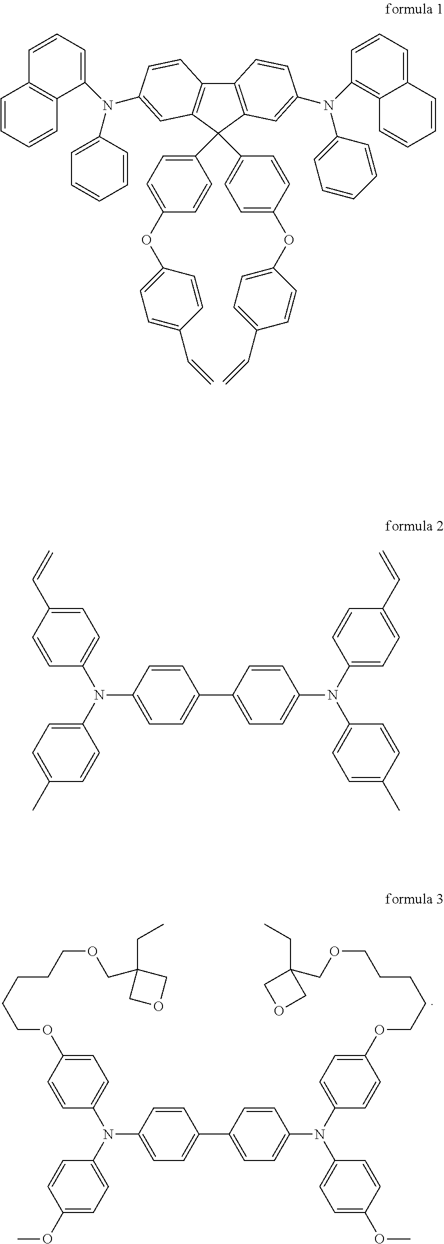 [SMILES: C=Cc1ccc(Oc2ccc(C3(c4ccc(Oc5ccc(C=C)cc5)cc4)c4cc(N(c5ccccc5)c5cccc6ccccc56)ccc4-c4ccc(N(c5ccccc5)c5cccc6ccccc56)cc43)cc2)cc1 ; C=Cc1ccc(N(c2ccc(C)cc2)c2ccc(-c3ccc(N(c4ccc(C)cc4)c4ccc(C=C)cc4)cc3)cc2)cc1 ; CCC1(COCCCCCOc2ccc(N(c3ccc(OC)cc3)c3ccc(-c4ccc(N(c5ccc(OC)cc5)c5ccc(OCCCCCOCC6(CC)COC6)cc5)cc4)cc3)cc2)COC1]

According to an embodiment of the invention, the first charge injection layer is an electron injection layer, the first charge transport layer is an electron transport layer, and the second charge injection layer is an hole injection layer, wherein the crosslinkable material includes a compound represented by the following formula 4, a compound represented by the following formula 5, or a compound represented by the following formula 6:

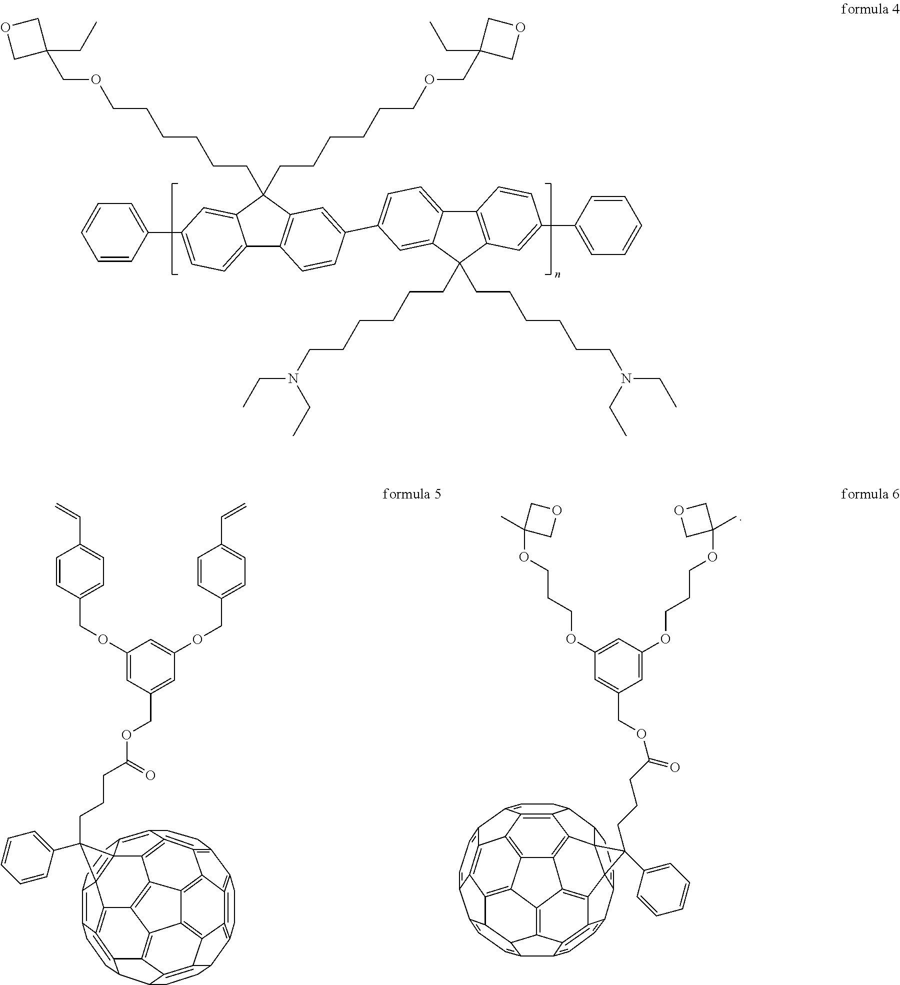

According to an embodiment of the invention, in the fabricating method of the perovskite light-emitting device, forming a second charge transport layer on the light-emitting layer before forming the second charge injection layer on the light-emitting layer is further included.

According to an embodiment of the invention, the method of forming the first charge injection layer, the first charge transport layer, the light-emitting layer, the second charge transport layer, and the second charge injection layer is a solution process.

According to an embodiment of the invention, a solution containing the crosslinkable material is used in the solution process of forming the first charge transport layer, wherein the concentration of the crosslinkable material is 0.01 wt % to 100 wt %.

Based on the above mentioned, in the present invention, the perovskite light-emitting device includes the first electrode layer, the first charge injection layer, the first charge transport layer, the light-emitting layer, the second charge injection layer, and the second electrode layer sequentially from bottom to top. Further, the material of the first charge transport layer includes the crosslinkable material, and the material of the light-emitting layer includes the light-emitting material having the perovskite crystal structure. Thus, the perovskite light-emitting device of the present invention exhibits high brightness, light-emitting efficiency, and device efficiency.

In order to make the aforementioned features and advantages of the disclosure more comprehensible, embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic cross-sectional diagram illustrating a perovskite light-emitting device according to an embodiment of the invention.

FIG. 2 is a schematic cross-sectional diagram illustrating a perovskite light-emitting device according to another embodiment of the invention.

FIG. 3 is a schematic cross-sectional diagram illustrating a perovskite light-emitting device according to yet another embodiment of the invention.

FIG. 4 is a schematic cross-sectional diagram illustrating a perovskite light-emitting device according to yet a further embodiment of the invention.

FIG. 5 is a diagram illustrating the relationship between brightness and voltage of the perovskite light-emitting device of each of Example 1 and Comparative Example 1.

FIG. 6 is a diagram illustrating the relationship between light-emitting efficiency and voltage of the perovskite light-emitting device of each of Example 1 and Comparative Example 1.

FIG. 7a and FIG. 7b are scanning electron microscope (SEM) top views of the perovskite light-emitting devices of Example 1 and Comparative Example 1, respectively.

### DESCRIPTION OF THE EMBODIMENTS

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

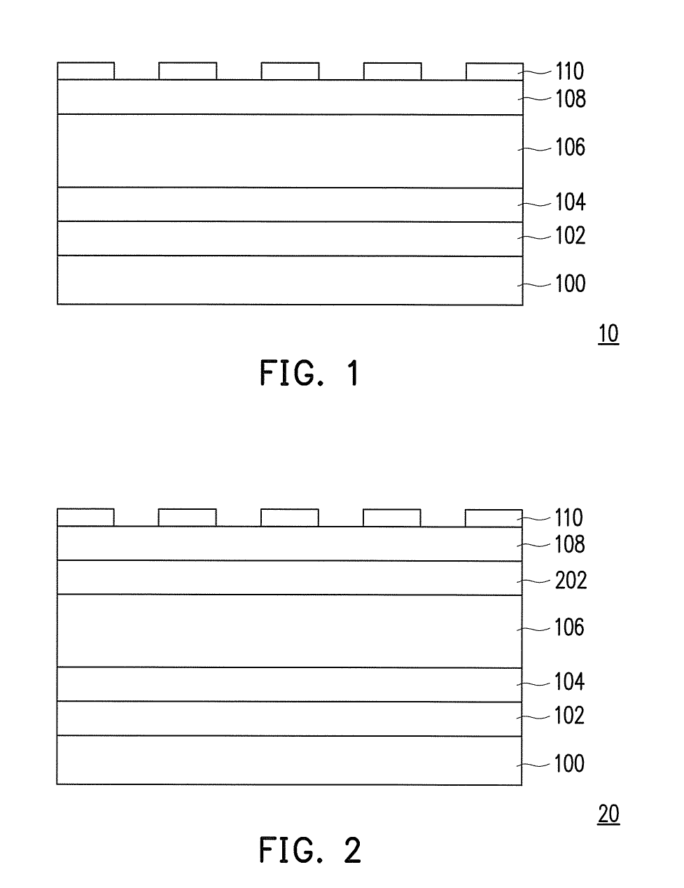

FIG. 1 is a schematic cross-sectional diagram illustrating a perovskite light-emitting device according to an embodiment of the invention. Referring to FIG. 1, a perovskite light-emitting device 10 includes a first electrode layer 100, a first charge injection layer (herein, the first charge injection layer is an hole injection layer 102), a first charge transport layer (herein, the first charge transport layer is an hole transport layer 104), a light-emitting layer 106, a second charge injection layer (herein, the second charge injection layer is an electron injection layer 108), and a second electrode layer 110.

The first electrode layer 100 is a transparent conductive substrate, for example. Specifically, the transparent conductive substrate is glass or plastic coated with a transparent conductive material such as indium tin oxide (ITO), indium zinc oxide (IZO), indium cerium oxide (ICO), zinc oxide (ZnO), aluminum zinc oxide (AZO), indium zinc tin oxide (IZTO), gallium zinc oxide (GZO), or tin oxide (SnO). Additionally, in the present embodiment, the first electrode layer 100 is used as an anode; the thickness of the first electrode layer 100 is 100 nm to 100000 nm, for example.

The hole injection layer 102 is disposed on the first electrode layer 100. Specifically, the hole injection layer 102 is primarily a film layer having a function of improving hole injection efficiency from the first electrode layer 100 (anode). In the present embodiment, the material of the hole injection layer 102 includes poly(3,4-ethylenedioxythiophene):poly(styrenesulfonate) (PEDOT:PSS), polyaniline, polypyrrole, or polyacetylene, for example. The thickness of the hole injection layer 102 is 1 nm to 1000 nm, for example.

Additionally, in the present embodiment, the method of forming the hole injection layer 102 on the first electrode layer 100 is a solution process. Specifically, the method of forming the hole injection layer 102 on the first electrode layer 100 includes, for example, after forming a solution containing the hole injection material, coating the solution on the first electrode layer 100 by a coating process. The solvent used is not particularly limited, as long as it can dissolve the hole injection material. The solvent may be dimethylformamide (DMF), chlorobenzene, or dimethyl sulfoxide, for example. The concentration of the hole injection material is 0.01 wt % to 100 wt %, for example. The coating process is a spin-coating method, a casting method, a micro gravure coating method, a gravure coating method, a bar coating method, a roller coating method, a wire-bar coating method, a scraper coating method, a dip coating method, a spray coating method, a screen printing method, a flexographic printing method, an offset printing method, or an ink jet printing method, for example. It should be mentioned that, 1 wt % is equivalent to 10 milligrams per milliliter in this article.

The hole transport layer 104 is disposed on the hole injection layer 102. Specifically, the hole transport layer 104 is primarily used to assist transport of the holes from the hole injection layer 102 to the light-emitting layer 106. More specifically, in the present embodiment, the first electrode layer 100 has an appropriate work function compared to the light-emitting layer 106 by setting the hole injection layer 102 and the hole transport layer 104, thereby decreasing the energy barrier for the hole injection significantly and assisting the transport of the holes. Additionally, in the present embodiment, the hole transport layer 104 also has a function of blocking electron transport, and thus the hole transport layer 104 may also be used as an electron blocking layer.

In the present embodiment, the material of the hole transport layer 104 includes a crosslinkable material. Specifically, in the present embodiment, the crosslinkable material is the material having hole transport property and having a crosslinking group, wherein the crosslinking group includes a thermally induced crosslinking group or a light induced crosslinking group. In particular, the crosslinkable material includes, for example, a compound represented by the following formula 1, a compound represented by the following formula 2, or a compound represented by the following formula 3 as the thermally induced crosslinking material:

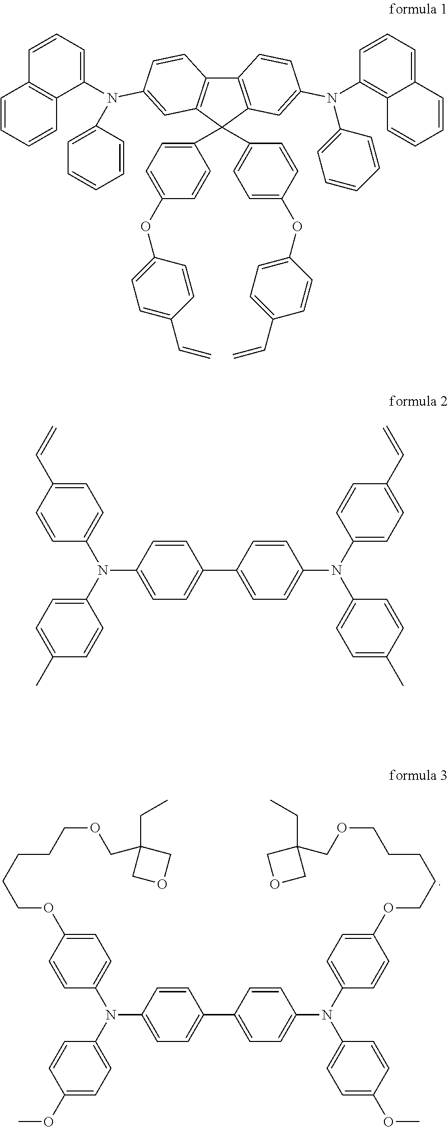 [SMILES: C=Cc1ccc(Oc2ccc(C3(c4ccc(Oc5ccc(C=C)cc5)cc4)c4cc(N(c5ccccc5)c5cccc6ccccc56)ccc4-c4ccc(N(c5ccccc5)c5cccc6ccccc56)cc43)cc2)cc1 ; C=Cc1ccc(N(c2ccc(C)cc2)c2ccc(-c3ccc(N(c4ccc(C)cc4)c4ccc(C=C)cc4)cc3)cc2)cc1 ; CCC1(COCCCCCOc2ccc(N(c3ccc(OC)cc3)c3ccc(-c4ccc(N(c5ccc(OC)cc5)c5ccc(OCCCCCOCC6(CC)COC6)cc5)cc4)cc3)cc2)COC1]

The thickness of the hole transport layer 104 is 1 nm to 1000 nm, for example.

Additionally, in the present embodiment, the method of forming the hole transport layer 104 on the hole injection layer 102 is a solution process. Specifically, the method of forming the hole transport layer 104 on the hole injection layer 102 includes, for example, the following steps. After forming a solution containing the crosslinkable material, the solution is coated on the hole injection layer 102 by a coating process. Then, the coated hole injection layer 102 undergoes a crosslinking reaction by heating or irradiation. The solvent used is not particularly limited, as long as it can dissolve the crosslinkable material. The solvent may be dimethylformamide, chlorobenzene, or dimethyl sulfoxide, for example. The concentration of the crosslinkable material is 0.01 wt % to 100 wt %, for example. The coating process is a spin-coating method, a casting method, a micro gravure coating method, a gravure coating method, a bar coating method, a roller coating method, a wire-bar coating method, a scraper coating method, a dip coating method, a spray coating method, a screen printing method, a flexographic printing method, an offset printing method, or an ink jet printing method, for example.

The light-emitting layer 106 is disposed on the hole transport layer 104. Specifically, the light-emitting layer 106 can emit light while driven by electrical power. In the present embodiment, the material of the light-emitting layer 106 includes a light-emitting material having a perovskite crystal structure which may be an organic-inorganic hybrid light-emitting material having the perovskite crystal structure or an inorganic light-emitting material having the perovskite crystal structure.

In an embodiment, when the light-emitting material having the perovskite crystal structure belongs to an organic-inorganic hybrid material, the light-emitting material having the perovskite crystal structure can have a structure represented by the following formula (I):

ABX₃ (I)

wherein A is an organic ammonium cation; B is a group IV metal cation or a transition metal cation; X₃ are a combination of single type halogen-containing anion or a combination of multiple type halogen-containing anion. Specifically, the organic ammonium cation is a C₁ to C₅₀ alkyl ammonium cation or an aromatic ammonium cation; the group IV metal cation is Pb²⁺, Ge²⁺, or Sn²⁺; the transition metal cation is Cu²⁺, Ni²⁺, Co²⁺, Fe²⁺, Mn²⁺, or Eu²⁺; the single type halogen-containing anion is Cl⁻, Br⁻, or the combination of multiple type halogen-containing anion has the following general formula: —Cl⁻ₓBr⁻_{y}I⁻_{z}, wherein x+y+z=3. In particular, the light-emitting material having the perovskite crystal structure is CH₃NH₃PbBr₃, CH₃NH₃PbBr₂I, CH₃NH₃PbCl₃, or CH₃NH₃PbBrCl₂, for example.

In another embodiment, when the light-emitting material having the perovskite crystal structure belongs to an inorganic material, the light-emitting material having the perovskite crystal structure includes CsPbCl₃, CsPbBrCl₂, or CsSnCl₃, for example.

Additionally, in the present embodiment, the thickness of the light-emitting layer 106 is 5 nm to 1000 nm, for example.

Additionally, in the present embodiment, the method of forming the light-emitting layer 106 on the hole transport layer 104 is a solution process. Specifically, the method of forming the light-emitting layer 106 on the hole transport layer 104 includes, for example, after forming a solution containing the light-emitting material having the perovskite crystal structure, coating the solution on the hole transport layer 104 by a coating process. The solvent used is not particularly limited, as long as it can dissolve the light-emitting material. The solvent may be dimethylformamide, chlorobenzene, or dimethyl sulfoxide, for example. The concentration of the light-emitting material is 0.01 wt % to 100 wt %, for example. The coating process is a spin-coating method, a casting method, a micro gravure coating method, a gravure coating method, a bar coating method, a roller coating method, a wire-bar coating method, a scraper coating method, a dip coating method, a spray coating method, a screen printing method, a flexographic printing method, an offset printing method, or an ink jet printing method, for example.

The electron injection layer 108 is disposed on the light-emitting layer 106. Specifically, the electron injection layer 108 is primarily a film layer having a function of improving electron injection efficiency from the second electrode layer 110 (the related description will be described hereinafter). In the present embodiment, the material of the electron injection layer 108 includes [6,6]-phenyl-C61-butyric acid methyl ester (PCBM), 4,7-diphenyl-1,10-phenanthroline (BPhen), or tris(2,4,6-triMethyl-3-(pyridin-3-yl)phenyl)borane (3TPYMB), for example. The thickness of the electron injection layer 108 is 1 nm to 1000 nm, for example.

Additionally, in the present embodiment, the method of forming the electron injection layer 108 on the light-emitting layer 106 may be a solution process or a vacuum vapor deposition process. Specifically, the method of forming the electron injection layer 108 on the light-emitting layer 106 using the solution process includes, for example, after forming a solution containing the electron injection material, coating the solution on the light-emitting layer 106 by a coating process. The solvent used is not particularly limited, as long as it can dissolve the electron injection material. The solvent may be dimethylformamide, chlorobenzene, or dimethyl sulfoxide, for example. The concentration of the electron injection material is 0.01 wt % to 100 wt %, for example. The coating process is a spin-coating method, a casting method, a micro gravure coating method, a gravure coating method, a bar coating method, a roller coating method, a wire-bar coating method, a scraper coating method, a dip coating method, a spray coating method, a screen printing method, a flexographic printing method, an offset printing method, or an ink jet printing method, for example.

The second electrode layer 110 is disposed on the electron injection layer 108. Specifically, the material of the second electrode layer 110 includes a metal material, such as silver, magnesium, or calcium. Additionally, in the present embodiment, the second electrode layer 110 is used as a cathode; the thickness of the second electrode layer 110 is 10 nm to 5000 nm, for example. Additionally, in the present embodiment, the method of forming the second electrode layer 110 on the electron injection layer 108 is a vapor deposition method, for example.

It should be mentioned that, as described above, the holes may be transported from the first electrode layer 100 to the light-emitting layer 106 by the hole injection layer 102 and the hole transport layer 104, and the electrons may be transported from the second electrode layer 110 to the light-emitting layer 106 by the electron injection layer 108. In this way, a recombination of two charge carriers (i.e. electrons and holes) may occur in the light-emitting layer 106 so as to emit light, and this is the light-emitting mechanism of the perovskite light-emitting device 10. Furthermore, in terms of the light-emitting mechanism, the perovskite light-emitting device 10 of the present embodiment can be regarded as a light-emitting diode.

Additionally, as described above, in the perovskite light-emitting device 10, by setting the hole injection layer 102 and the hole transport layer 104, the energy barrier for the hole injection is significantly decreased. Thereby, the hole injection efficiency is effectively increased, and therefore the brightness and the light-emitting efficiency are increased.

Additionally, in the perovskite light-emitting device 10, by using the crosslinkable material as the material of the hole transport layer 104, the number of holes in the surface morphology of the light-emitting layer 106 formed thereon is effectively reduced, thereby reducing the leakage current of the perovskite light-emitting device 10, and thus the device efficiency is increased.

Additionally, in the perovskite light-emitting device 10, since the material of the hole transport layer 104 includes the crosslinkable material, which is capable of performing the crosslinking reaction, the hole transport layer 104 is not dissolved and damaged by the solvent in the solution process of forming the light-emitting layer 106. In this way, the hole injection layer 102, the hole transport layer 104, the light-emitting layer 106, and the electron injection layer 108 in the perovskite light-emitting device 10 can all be fabricated by the solution process. Thereby, the fabricating method of the perovskite light-emitting device 10 has the advantages of simple process and low cost.

FIG. 2 is a schematic cross-sectional diagram illustrating a perovskite light-emitting device according to another embodiment of the invention. Referring to FIG. 2 and FIG. 1 at the same time, a perovskite light-emitting device 20 of FIG. 2 is similar to the perovskite light-emitting device 10 of FIG. 1. Therefore, similar or identical components are designated with similar or identical element symbols, and the related description is not repeated here. Hereinafter, the difference between the two will be described, and the same of the two is referred to the aforementioned description according to the symbols in FIG. 1.

Referring to FIG. 2 and FIG. 1 at the same time, the difference between the perovskite light-emitting device 20 of FIG. 2 and the perovskite light-emitting device 10 of FIG. 1 lies in that: the perovskite light-emitting device 20 further includes a second charge transport layer disposed between the light-emitting layer 106 and the electron injection layer 108. Herein, the second charge transport layer is an electron transport layer 202. Specifically, the electron transport layer 202 is primarily used to assist the transport of the electrons from the electron injection layer 108 to the light-emitting layer 106. In the present embodiment, the material of the electron transport layer 202 includes 3,5-diphenyl-4-(1-naphthyl)-1H-1,2,4-triazole (TAZ), 3,3′-[5′-[3-(3-pyridinyl)phenyl][1,1′:3′,1″-terphenyl]-3,3′-diyl]bispyridine (Tm3PyPB), or ZnO, for example. The thickness of the electron transport layer 202 is 1 nm to 1000 mn, for example.

Additionally, in the present embodiment, the method of forming the electron transport layer 202 on the light-emitting layer 106 is a solution process. Specifically, the method of forming the electron transport layer 202 on the light-emitting layer 106 includes, for example, after forming a solution containing the electron transport material, coating the solution on the light-emitting layer 106 by a coating process. The solvent used is not particularly limited, as long as it can dissolve the electron transport material. The solvent may be dimethylformamide, chlorobenzene, or dimethyl sulfoxide, for example. The concentration of the electron transport material is 0.01 wt % to 100 wt %, for example. The coating process is a spin-coating method, a casting method, a micro gravure coating method, a gravure coating method, a bar coating method, a roller coating method, a wire-bar coating method, a scraper coating method, a dip coating method, a spray coating method, a screen printing method, a flexographic printing method, an offset printing method, or an ink jet printing method, for example.

It should be mentioned that, the hole injection layer 102, the hole transport layer 104, the light-emitting layer 106, the electron transport layer 202, and the electron injection layer 108 in the perovskite light-emitting device 20 can all be fabricated by the solution process. Therefore, the fabricating method of the perovskite light-emitting device 20 has the advantages of simple process and low cost.

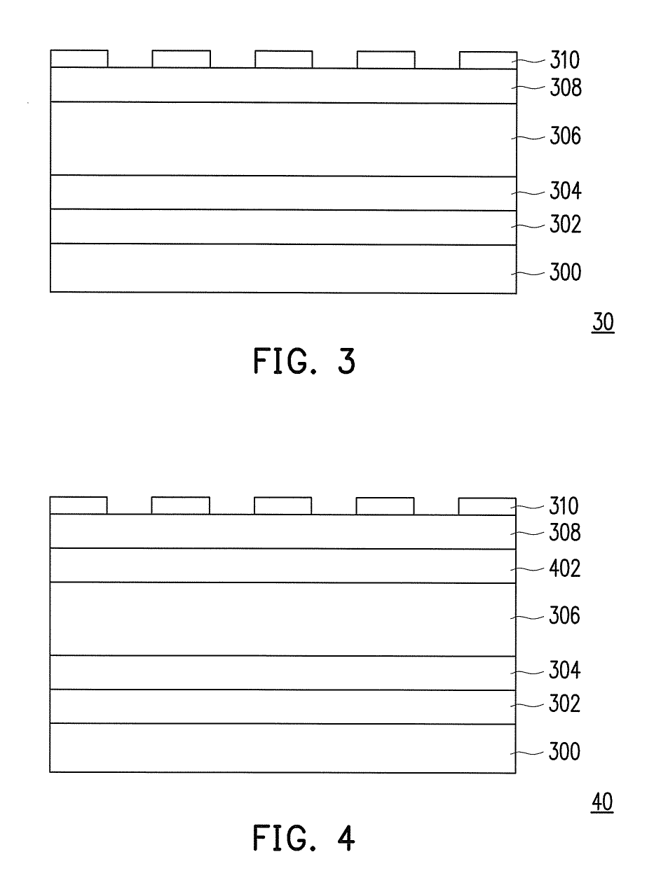

Additionally, in the embodiments of FIG. 1 and FIG. 2, the first charge injection layer is the hole injection layer 102, the first charge transport layer is the hole transport layer 104, the second charge injection layer is the electron injection layer 108, and the second charge transport layer is the electron transport layer 202. However, the invention is not limited thereto. In other embodiments, the first charge injection layer may be the electron injection layer, the first charge transport layer may be the electron transport layer, the second charge injection layer may be the hole injection layer, and the second charge transport layer may be the hole transport layer. Hereinafter, it will be described in detail with reference to FIG. 3 and FIG. 4.

FIG. 3 is a schematic cross-sectional diagram illustrating a perovskite light-emitting device according to yet another embodiment of the invention. Referring to FIG. 3, a perovskite light-emitting device 30 includes a first electrode layer 300, an electron injection layer 302, an electron transport layer 304, a light-emitting layer 306, an hole injection layer 308, and a second electrode layer 310.

The first electrode layer 300 is a transparent conductive substrate, for example. Specifically, the transparent conductive substrate is glass or plastic coated with a transparent conductive material such as indium tin oxide, indium zinc oxide, indium cerium oxide, zinc oxide, aluminum zinc oxide, indium zinc tin oxide, gallium zinc oxide, or tin oxide. Additionally, in the present embodiment, the first electrode layer 300 is used as a cathode; the thickness of the first electrode layer 300 is 100 nm to 100000 nm, for example.

The electron injection layer 302 is disposed on the first electrode layer 300. Specifically, the electron injection layer 302 is primarily a film layer having a function of improving the electron injection efficiency from the first electrode layer 300 (cathode). In the present embodiment, the material of the electron injection layer 302 includes polyethylenimine ethoxylated (PEIE), Cs₂CO₃, or Li-doped 4,7-diphenyl-1,10-phenanthroline (Li-doped BPhen), for example. The thickness of the electron injection layer 302 is 1 nm to 1000 nm, for example.

Additionally, in the present embodiment, the method of forming the electron injection layer 302 on the first electrode layer 300 is a solution process. Specifically, the method of forming the electron injection layer 302 on the first electrode layer 300 includes, for example, after forming a solution containing the electron injection material, coating the solution on the first electrode layer 300 by a coating process. The solvent used is not particularly limited, as long as it can dissolve the electron injection material. The solvent may be dimethylformamide, chlorobenzene, or dimethyl sulfoxide, for example. The concentration of the electron injection material is 0.01 wt % to 10 wt %, for example. The coating process is a spin-coating method, a casting method, a micro gravure coating method, a gravure coating method, a bar coating method, a roller coating method, a wire-bar coating method, a scraper coating method, a dip coating method, a spray coating method, a screen printing method, a flexographic printing method, an offset printing method, or an ink jet printing method, for example.

The electron transport layer 304 is disposed on the electron injection layer 302. Specifically, the electron transport layer 304 is primarily used to assist the transport of the electrons from the electron injection layer 302 to the light-emitting layer 306. More specifically, in the present embodiment, the first electrode layer 300 has an appropriate work function compared to the light-emitting layer 306 by setting the electron injection layer 302 and the electron transport layer 304, thereby decreasing the energy barrier for the electron injection significantly and assisting the transport of the electrons. Additionally, in the present embodiment, the electron transport layer 304 also has a function of blocking hole transport, and thus the electron transport layer 304 may also be used as an hole blocking layer.

In the present embodiment, the material of the electron transport layer 304 includes a crosslinkable material. Specifically, in the present embodiment, the crosslinkable material is the material having electron transport property and having a crosslinking group, wherein the crosslinking group includes a thermally induced crosslinking group or a light induced crosslinking group. In particular, the crosslinkable material includes, for example, a compound represented by the following formula 4, a compound represented by the following formula 5, or a compound represented by the following formula 6 as the thermally induced crosslinking material:

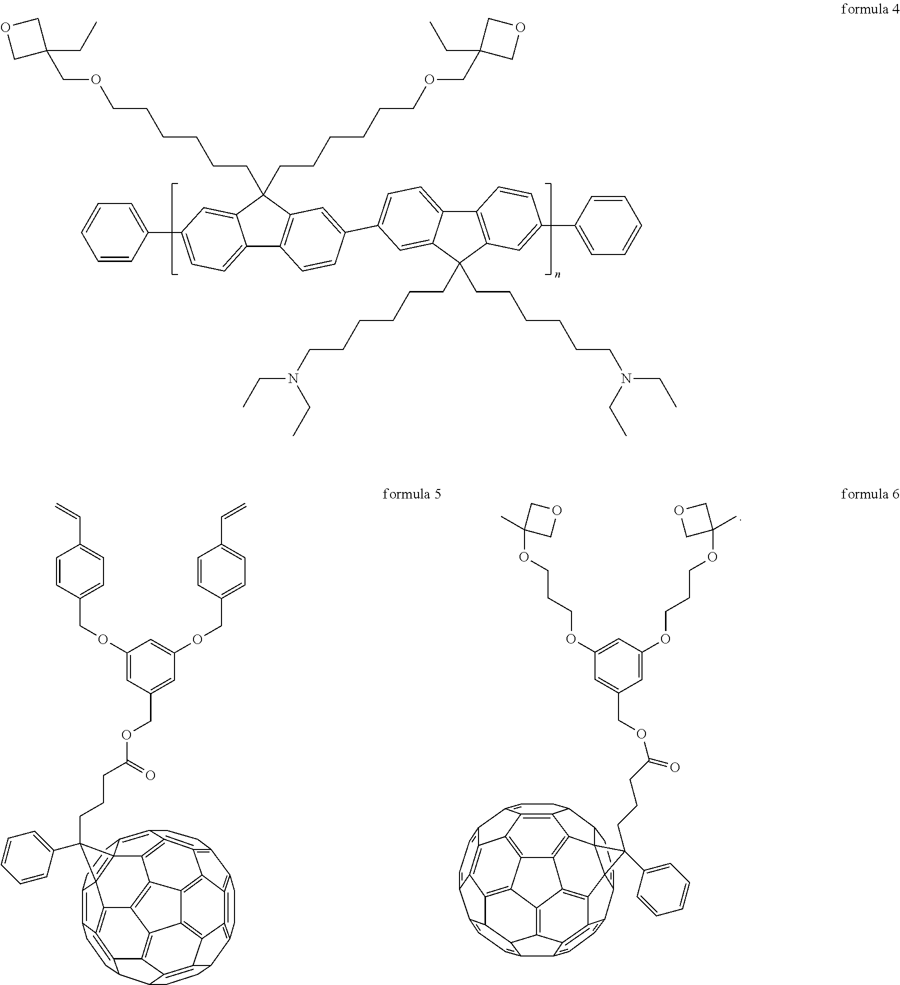

The thickness of the electron transport layer 304 is 1 nm to 1000 nm, for example.

Additionally, in the present embodiment, the method of forming the electron transport layer 304 on the electron injection layer 302 is a solution process. Specifically, the method of forming the electron transport layer 304 on the electron injection layer 302 includes, for example, the following steps. After forming a solution containing the crosslinkable material, the solution is coated on the electron injection layer 302 by a coating process. Then, the coated electron injection layer 302 undergoes a crosslinking reaction by heating or irradiation. The solvent used is not particularly limited, as long as it can dissolve the crosslinkable material. The solvent may be dimethylformamide, chlorobenzene, or dimethyl sulfoxide, for example. The concentration of the crosslinkable material is 0.01 wt % to 100 wt %, for example. The coating process is a spin-coating method, a casting method, a micro gravure coating method, a gravure coating method, a bar coating method, a roller coating method, a wire-bar coating method, a scraper coating method, a dip coating method, a spray coating method, a screen printing method, a flexographic printing method, an offset printing method, or an ink jet printing method, for example.

The light-emitting layer 306 is disposed on the electron transport layer 304. Specifically, the light-emitting layer 306 can emit light while driven by electrical power. In the present embodiment, the material of the light-emitting layer 306 includes a light-emitting material having a perovskite crystal structure which may be an organic-inorganic hybrid light-emitting material having the perovskite crystal structure or an inorganic light-emitting material having the perovskite crystal structure.

In an embodiment, when the light-emitting material having the perovskite crystal structure belongs to an organic-inorganic hybrid material, the light-emitting material having the perovskite crystal structure can have a structure represented by the following formula (I):

ABX₃ (I)

wherein A is an organic ammonium cation; B is a group IV metal cation or a transition metal cation; X₃ are a combination of single type halogen-containing anion or a combination of multiple type halogen-containing anion. Specifically, the organic ammonium cation is a C₁ to C₅₀ alkyl ammonium cation or an aromatic ammonium cation; the group IV metal cation is Pb²⁺, Ge²⁺, or Sn²⁺; the transition metal cation is Cu²⁺, Ni²⁺, Co²⁺, Fe²⁺, Mn²⁺, or Eu²⁺; the single type halogen-containing anion is Cl⁻, Br⁻, or I⁻; the combination of multiple type halogen-containing anion has the following general formula: —Cl⁻ₓBr⁻_{y}I⁻_{z}, wherein x+y+z=3. In particular, the light-emitting material having the perovskite crystal structure is CH₃NH₃PbBr₃, CH₃NH₃PbBr₂I, CH3NH₃PbCl₃, or CH₃NH₃PbBrCl₂, for example.

In another embodiment, when the light-emitting material having the perovskite crystal structure belongs to an inorganic material, the light-emitting material having the perovskite crystal structure includes CsPbCl₃, CsPbBrCl₂, or CsSnCl₃, for example.

Additionally, in the present embodiment, the thickness of the light-emitting layer 306 is 5 nm to 1000 nm, for example.

Additionally, in the present embodiment, the method of forming the light-emitting layer 306 on the electron transport layer 304 is a solution process. Specifically, the method of forming the light-emitting layer 306 on the electron transport layer 304 includes, for example, after forming a solution containing the light-emitting material having the perovskite crystal structure, coating the solution on the electron transport layer 304 by a coating process. The solvent used is not particularly limited, as long as it can dissolve the light-emitting material. The solvent may be dimethylformamide, chlorobenzene, or dimethyl sulfoxide, for example. The concentration of the light-emitting material is 0.01 wt % to 100 wt %, for example. The coating process is a spin-coating method, a casting method, a micro gravure coating method, a gravure coating method, a bar coating method, a roller coating method, a wire-bar coating method, a scraper coating method, a dip coating method, a spray coating method, a screen printing method, a flexographic printing method, an offset printing method, or an ink jet printing method, for example.

The hole injection layer 308 is disposed on the light-emitting layer 306. Specifically, the hole injection layer 308 is primarily a film layer having a function of improving the electron hole injection efficiency from the second electrode layer 310 (the related description will be described hereinafter). In the present embodiment, the material of the hole injection layer 308 includes poly(3,4-ethylenedioxythiophene):poly(styrenesulfonate) (PEDOT:PSS), V₂O₅, or MoO₃, for example. The thickness of the hole injection layer 308 is 1 nm to 1000 nm, for example.

Additionally, in the present embodiment, the method of forming the hole injection layer 308 on the light-emitting layer 306 is a solution process. Specifically, the method of forming the hole injection layer 308 on the light-emitting layer 306 includes, for example, after forming a solution containing the electron hole injection material, coating the solution on the light-emitting layer 306 by a coating process. The solvent used is not particularly limited, as long as it can dissolve the electron hole injection material. The solvent may be dimethylformamide, chlorobenzene, or dimethyl sulfoxide, for example. The concentration of the electron hole injection material is 0.01 wt % to 100 wt %, for example. The coating process is a spin-coating method, a casting method, a micro gravure coating method, a gravure coating method, a bar coating method, a roller coating method, a wire-bar coating method, a scraper coating method, a dip coating method, a spray coating method, a screen printing method, a flexographic printing method, an offset printing method, or an ink jet printing method, for example.

The second electrode layer 310 is disposed on the hole injection layer 308. Specifically, the material of the second electrode layer 310 includes a metal material, such as gold, silver, or palladium. Additionally, in the present embodiment, the second electrode layer 310 is used as an anode; the thickness of the second electrode layer 310 is 10 nm to 5000 nm, for example. Additionally, in the present embodiment, the method of forming the second electrode layer 310 on the hole injection layer 308 is a vapor deposition method, for example.

It should be mentioned that, as described above, the electrons may be transported from the first electrode layer 300 to the light-emitting layer 306 by the electron injection layer 302 and the electron transport layer 304, and the holes may be transported from the second electrode layer 310 to the light-emitting layer 306 by the hole injection layer 308. In this way, a recombination of two charge carriers (i.e. electrons and holes) may occur in the light-emitting layer 306 so as to emit light, and this is the light-emitting mechanism of the perovskite light-emitting device 30. Furthermore, in terms of the light-emitting mechanism, the perovskite light-emitting device 30 of the present embodiment can be regarded as a light-emitting diode.

Additionally, as described above, in the perovskite light-emitting device 30, by setting the electron injection layer 302 and the electron transport layer 304, the energy barrier for the electron injection is significantly decreased. Thereby, the electron injection efficiency is effectively increased, and therefore the brightness and the light-emitting efficiency are increased.

Additionally, in the perovskite light-emitting device 30, by using the crosslinkable material as the material of the electron transport layer 304, the number of holes in the surface morphology of the light-emitting layer 306 formed thereon is effectively reduced, thereby reducing the leakage current of the perovskite light-emitting device 30, and thus the device efficiency is increased.

Additionally, in the perovskite light-emitting device 30, since the material of the electron transport layer 304 includes the crosslinkable material, which is capable of performing the crosslinking reaction, the electron transport layer 304 is not dissolved and damaged by the solvent in the solution process of foil ling the light-emitting layer 306. In this way, the electron injection layer 302, the electron transport layer 304, the light-emitting layer 306, and the hole injection layer 308 in the perovskite light-emitting device 30 can all be fabricated by the solution process. Thereby, the fabricating method of the perovskite light-emitting device 30 has the advantages of simple process and low cost.

FIG. 4 is a schematic cross-sectional diagram illustrating a perovskite light-emitting device according to yet a further embodiment of the invention. Referring to FIG. 4 and FIG. 3 at the same time, a perovskite light-emitting device 40 of FIG. 4 is similar to the perovskite light-emitting device 30 of FIG. 3. Therefore, similar or identical components are designated with similar or identical element symbols, and the related description is not repeated here. Hereinafter, the difference between the two will be described, and the same of the two is referred to the aforementioned description according to the symbols in FIG. 3.

Referring to FIG. 4 and FIG. 3 at the same time, the difference between the perovskite light-emitting device 40 of FIG. 4 and the perovskite light-emitting device 30 of FIG. 3 lies in that: the perovskite light-emitting device 40 further includes an hole transport layer 402 disposed between the light-emitting layer 306 and the hole injection layer 308. Specifically, the hole transport layer 402 is primarily used to assist the transport of the holes from the hole injection layer 308 to the light-emitting layer 306. In the present embodiment, the material of the hole transport layer 402 includes, for example, a compound represented by the following formula 7, a compound represented by the following formula 8, or a compound represented by the following formula 9:

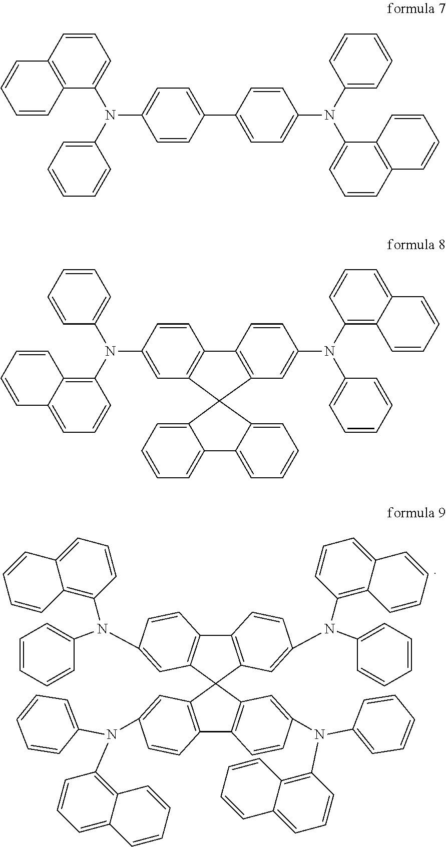 [SMILES: c1ccc(N(c2ccc(-c3ccc(N(c4ccccc4)c4cccc5ccccc45)cc3)cc2)c2cccc3ccccc23)cc1 ; c1ccc(N(c2ccc3c(c2)C2(c4ccccc4-c4ccccc42)c2cc(N(c4ccccc4)c4cccc5ccccc45)ccc2-3)c2cccc3ccccc23)cc1 ; c1ccc(N(c2ccc3c(c2)C2(c4cc(N(c5ccccc5)c5cccc6ccccc56)ccc4-3)c3cc(N(c4ccccc4)c4cccc5ccccc45)ccc3-c3ccc(N(c4ccccc4)c4cccc5ccccc45)cc32)c2cccc3ccccc23)cc1]

The thickness of the hole transport layer 402 is 1 rim to 1000 nm, for example.

Additionally, in the present embodiment, the method of forming the hole transport layer 402 on the light-emitting layer 306 is a solution process. Specifically, the method of forming the hole transport layer 402 on the light-emitting layer 306 includes, for example, after forming a solution containing the electron hole transport material, coating the solution on the light-emitting layer 106 by a coating process. The solvent used is not particularly limited, as long as it can dissolve the electron hole transport material. The solvent may be dimethylformamide, chlorobenzene, or dimethyl sulfoxide, for example. The concentration of the electron hole transport material is 0.01 wt % to 100 wt %, for example. The coating process is a spin-coating method, a casting method, a micro gravure coating method, a gravure coating method, a bar coating method, a roller coating method, a wire-bar coating method, a scraper coating method, a dip coating method, a spray coating method, a screen printing method, a flexographic printing method, an offset printing method, or an ink jet printing method, for example.

It should be mentioned that, the electron injection layer 302, the electron transport layer 304, the light-emitting layer 306, the hole transport layer 402, and the hole injection layer 308 in the perovskite light-emitting device 40 can all be fabricated by the solution process. Therefore, the fabricating method of the perovskite light-emitting device 40 has the advantages of simple process and low cost.

The features of the invention are more specifically described in the following with reference to Example 1 and Comparative Example 1. Although the following Example 1 is described, the material used, the material usage amount and ratio, processing details and processing procedures, etc., can be suitably modified without departing from the scope of the invention. Accordingly, restrictive interpretation should not be made to the invention based on the examples described below.

### EXAMPLE 1

First, an ITO glass substrate having a sheet resistance of 15 Ω/cm² was cut into the dimension of 15 mm×15 mm to be used as a first electrode layer. The ITO glass substrate was ultrasonic cleaned by an isopropyl alcohol solution, an acetone solution and deionized water and then dried by dry nitrogen gas after cleaning. Next, a PEDOT:PSS solution was spin-coated on the cleaned ITO glass substrate and then dried for 100 minutes to be used as an hole injection layer. After that, a solution of the compound represented by formula 1 with the concentration of 1.2 wt % in dimethyl formamide (DMF) solvent was spin-coated on the hole injection layer and then soft-baked at 100° C. for 30 minutes. Next, the soft-baked hole injection layer underwent a crosslinking reaction at 230° C. for 90 minutes to be used as an hole transport layer. Then, a CH₃NH₃PbBr₃ solution was formed by dissolving PbBr₂ and CH₃NH₃Br in a molar concentration ratio of 0.67 M to 2.2 M in DMF solvent. Then, the CH₃NH₃PbBr₃ solution was spin-coated on the hole transport layer and then heated at 100° C. for 120 minutes to be used as a light-emitting layer. After that, a PCBM solution with the concentration of 2 wt % in chlorobenzene solvent was spin-coated on the light-emitting layer and then heated at 100° C. for 15 minutes to be used as an electron injection layer. Then, a silver electrode, which was used as a second electrode layer, was thermally vapor deposited on the electron injection layer, so as to complete the fabrication of the perovskite light-emitting device of Example 1.

Specifically, the perovskite light-emitting device of Example 1 has the structure represented by FIG. 1, and the structure is: ITO glass substrate (200 nm)/PEDOT:PSS (45 nm)/the compound represented by formula 1 (50 nm)/CH₃NH₃PbBr₃ (450 nm)/PCBM (30 nm)/Ag(100 nm).

### COMPARATIVE EXAMPLE 1

First, an ITO glass substrate having a sheet resistance of 15 Ω/cm² was cut into the dimension of 15 mm×5 mm to be used as a first electrode layer. The ITO glass substrate was ultrasonic cleaned by an isopropyl alcohol solution, an acetone solution and deionized water and then dried by dry nitrogen gas after cleaning. Next, a PEDOT:PSS solution was spin-coated on the cleaned ITO glass substrate and then dried for 100 minutes to be used as an hole injection layer. Then, a CH₃NH₃PbBr₃ solution was formed by dissolving PbBr₂ and CH₃NH₃Br in s molar concentration ratio of 0.67 M to 2.2 M in DMF solvent. Then, the CH₃NH₃PbBr₃ solution was spin-coated on the hole injection layer and then heated at 100° C. for 120 minutes to be used as a light-emitting layer. After that, a PCBM solution with the concentration of 2 wt % in chlorobenzene solvent was spin-coated on the light-emitting layer and then heated at 100° C. for 15 minutes to be used as an electron injection layer. Then, a silver electrode, which was used as a second electrode layer, was thermally vapor deposited on the electron injection layer, so as to complete the fabrication of the perovskite light-emitting device of Comparative Example 1.

Specifically, compared to the perovskite light-emitting device of Example 1, the perovskite light-emitting device of Comparative Example 1 is not provided with the hole transport layer, and the structure thereof is: ITO glass substrate (200 nm)/PEDOT:PSS (45 nm)/CH₃NH₃PbBr₃ (450 nm)/PCBM (30 nm)/Ag (100 nm).

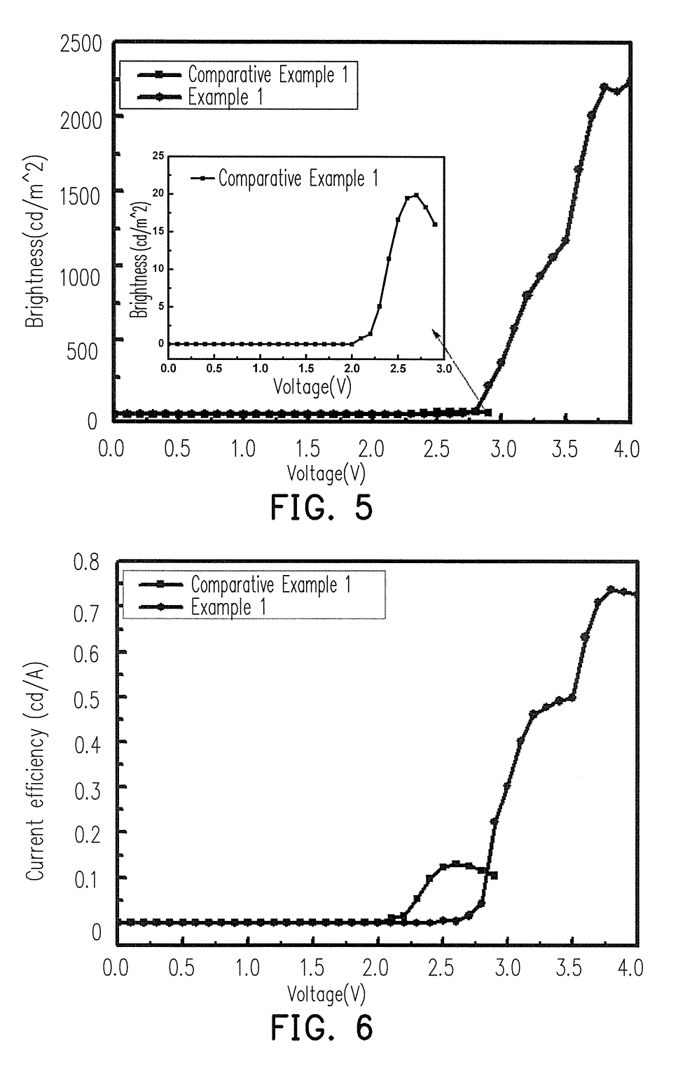

After fabricating the perovskite light-emitting devices of Example 1 and Comparative Example 1, the variation of brightness measured against voltage and light-emitting efficiency (also known as current efficiency) of the perovskite light-emitting device of each of Example 1 and Comparative Example 1 were measured, respectively, wherein the items were measured by the following methods, and the measurement results are shown in FIG. 4 and FIG. 5, respectively.

### <Measurement of Brightness Variation Against Voltage Variation>

Brightness of the perovskite light-emitting device of Example 1 was measured using a brightness meter as the voltage was increased from 0 V to 4 V; and brightness of the perovskite light-emitting device of Comparative Example 1 was measured as the voltage was increased from 0 V to 2.8 V. The measurement results were made for a curve diagram of brightness-voltage as shown in FIG. 5. FIG. 5 is a diagram illustrating the relationship between brightness and voltage of the perovskite light-emitting device of each of Example 1 and Comparative Example 1. Specifically, in the process of measuring the brightness of the perovskite light-emitting device of Comparative Example 1, since the brightness and the light-emitting efficiency had been decreased obviously at the voltage of 2.6 V, the voltage was not increased to 4 V.

### <Measurement of Light-Emitting Efficiency>

At the same current density (10 mA/m²), the measurement results of the brightness variation against voltage variation were used to calculate the current efficiency (cd/A), so as to make the curve diagram of current efficiency-voltage as shown in FIG. 6. FIG. 6 is a diagram illustrating the relationship between light-emitting efficiency and voltage of the perovskite light-emitting device of each of Example 1 and Comparative Example 1.

It can be known from FIG. 5, the maximum brightness of the perovskite light-emitting device of Comparative Example 1 is 19.5 cd/m², and the maximum brightness of the perovskite light-emitting device of Example 1 is 2249 cd/m². It means that the maximum brightness of the perovskite light-emitting device of Example 1 is increased by about 115 times compared to that of the perovskite light-emitting device of Comparative Example 1, and therefore the perovskite light-emitting device of Example 1 has the better brightness. Also, it can be known from FIG. 6, the maximum current efficiency of the perovskite light-emitting device of Comparative Example 1 is 0.12 cd/A, and the maximum current efficiency of the perovskite light-emitting device of Example 1 is 0.74 cd/A. It means that the maximum current efficiency of the perovskite light-emitting device of Example 1 is increased by about 6 times compared to that of the perovskite light-emitting device of Comparative Example 1, and therefore the perovskite light-emitting device of Example 1 has the better current efficiency. The results confirmed that, compared to the perovskite light-emitting device of Comparative Example 1, which is not provided with the hole transport layer including the crosslinkable material, the perovskite light-emitting device of Example 1 using the crosslinkable material as the material of the hole transport layer has a better device performance.

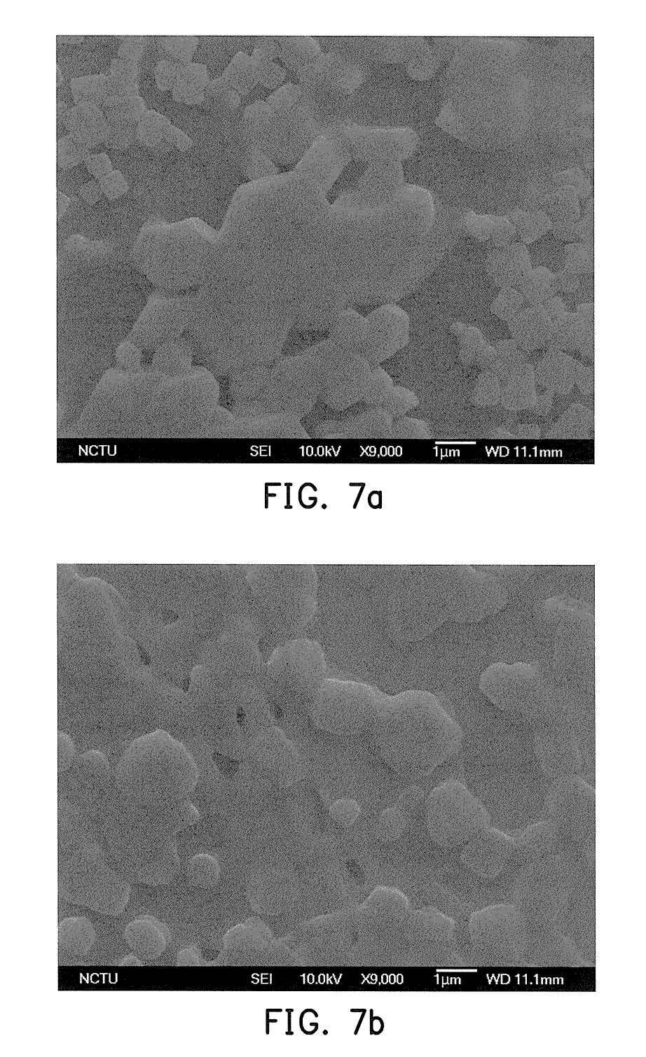

Additionally, to observe the surface morphology of the light-emitting layer of the perovskite light-emitting device of each of Example 1 and Comparative Example 1 clearly, in the process of fabricating the perovskite light-emitting devices of Example 1 and Comparative Example 1, the surface morphology thereof was observed by a scanning electron microscope (SEM) after forming the light-emitting layer, and the observation results are shown in FIG. 7a and FIG. 7b, respectively. FIG. 7a and FIG. 7b are scanning electron microscope (SEM) top views of the perovskite light-emitting devices of Example 1 and Comparative Example 1, respectively.

It can be known from FIG. 7a and FIG. 7b, the surface morphologies of the light-emitting layers of the perovskite light-emitting devices of Example 1 and Comparative Example 1 are completely different. Specifically, it can be known from FIG. 7a and FIG. 7b, crystallinity of the light-emitting layer in the perovskite light-emitting device of Comparative Example 1 was quite good, and the crystal shape of the light-emitting layer in the perovskite light-emitting device of Comparative Example 1 was also quite obvious, which resulted in many holes; and the light-emitting layer in the perovskite light-emitting device of Example 1 was good in film formation, and the number of holes was less. The results confirmed that, the surface morphology of the light-emitting layer can be effectively controlled by incorporating the crosslinkable material between the light-emitting layer and the hole injection layer, so that the number of holes is reduced, and the quality of film formation is improved, and thus the leakage current is reduced so as to enhance the device efficiency.

Although the invention has been described with reference to the above embodiments, it will be apparent to one of ordinary skill in the art that modifications to the described embodiments may be made without departing from the spirit of the invention. Accordingly, the scope of the invention is defined by the attached claims not by the above detailed descriptions.

What is claimed is:

1. A perovskite light-emitting device, comprising:
a first electrode layer;
a first charge injection layer disposed on the first electrode layer;
a first charge transport layer disposed on the first charge injection layer, wherein a material of the first charge transport layer comprises a crosslinkable material;
a light-emitting layer disposed on the first charge transport layer, wherein a material of the light-emitting layer comprises a light-emitting material having a perovskite crystal structure;
a second charge injection layer disposed on the light-emitting layer; and
a second electrode layer disposed on the second charge injection layer.

2. The perovskite light-emitting device according to claim 1, wherein the light-emitting material having the perovskite crystal structure has a structure represented by the following formula (I):
ABX₃ (I)
wherein A is an organic ammonium cation; B is a group IV metal cation or a transition metal cation; X₃ are a combination of single type halogen-containing anion or a combination of multiple type halogen-containing anion.

3. The perovskite light-emitting device according to claim 2, wherein the organic ammonium cation is a C₁ to C₅₀ alkyl ammonium cation or an aromatic ammonium cation; the group IV metal cation is Pb²⁺, Ge²⁺, or Sn²⁺; the transition metal cation is Cu²⁺, Ni²⁺, Co²⁺, Fe²⁺, Mn²⁺, or Eu²⁺; the single type halogen-containing anion is Cl⁻, Br⁻, I⁻; or the combination of multiple type halogen-containing anion has the following general formula: —Cl⁻ₓBr⁻_{y}I⁻_{z}, wherein x+y+z=3.

4. The perovskite light-emitting device according to claim 2, wherein the light-emitting material having the perovskite crystal structure is CH₃NH₃PbBr₃, CH₃NH₃PbBr₂I, CH₃NH₃PbCl₃, or CH₃NH₃PbBrCl₂.

5. The perovskite light-emitting device according to claim 1, wherein the first charge injection layer is an hole injection layer, the first charge transport layer is an hole transport layer, and the second charge injection layer is an electron injection layer.

6. The perovskite light-emitting device according to claim 5, wherein the crosslinkable material comprises a compound represented by the following formula 1, a compound represented by the following formula 2, or a compound represented by the following formula 3:

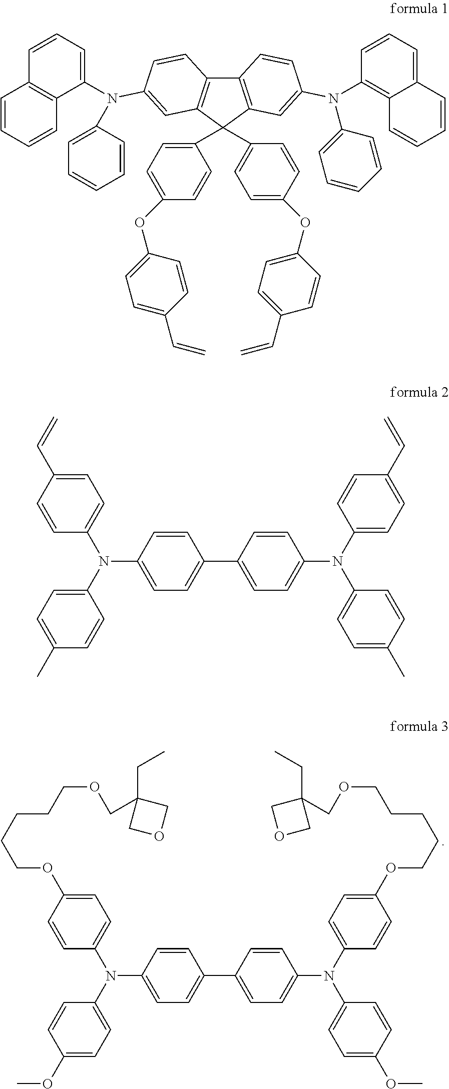 [SMILES: C=Cc1ccc(Oc2ccc(C3(c4ccc(Oc5ccc(C=C)cc5)cc4)c4cc(N(c5ccccc5)c5cccc6ccccc56)ccc4-c4ccc(N(c5ccccc5)c5cccc6ccccc56)cc43)cc2)cc1 ; C=Cc1ccc(N(c2ccc(C)cc2)c2ccc(-c3ccc(N(c4ccc(C)cc4)c4ccc(C=C)cc4)cc3)cc2)cc1 ; CCC1(COCCCCCOc2ccc(N(c3ccc(OC)cc3)c3ccc(-c4ccc(N(c5ccc(OC)cc5)c5ccc(OCCCCCOCC6(CC)COC6)cc5)cc4)cc3)cc2)COC1]

7. The perovskite light-emitting device according to claim 1, wherein the first charge injection layer is an electron injection layer, the first charge transport layer is an electron transport layer, and the second charge injection layer is an hole injection layer.

8. The perovskite light-emitting device according to claim 7, wherein the crosslinkable material comprises a compound represented by the following formula 4, a compound represented by the following formula 5, or a compound represented by the following formula 6:

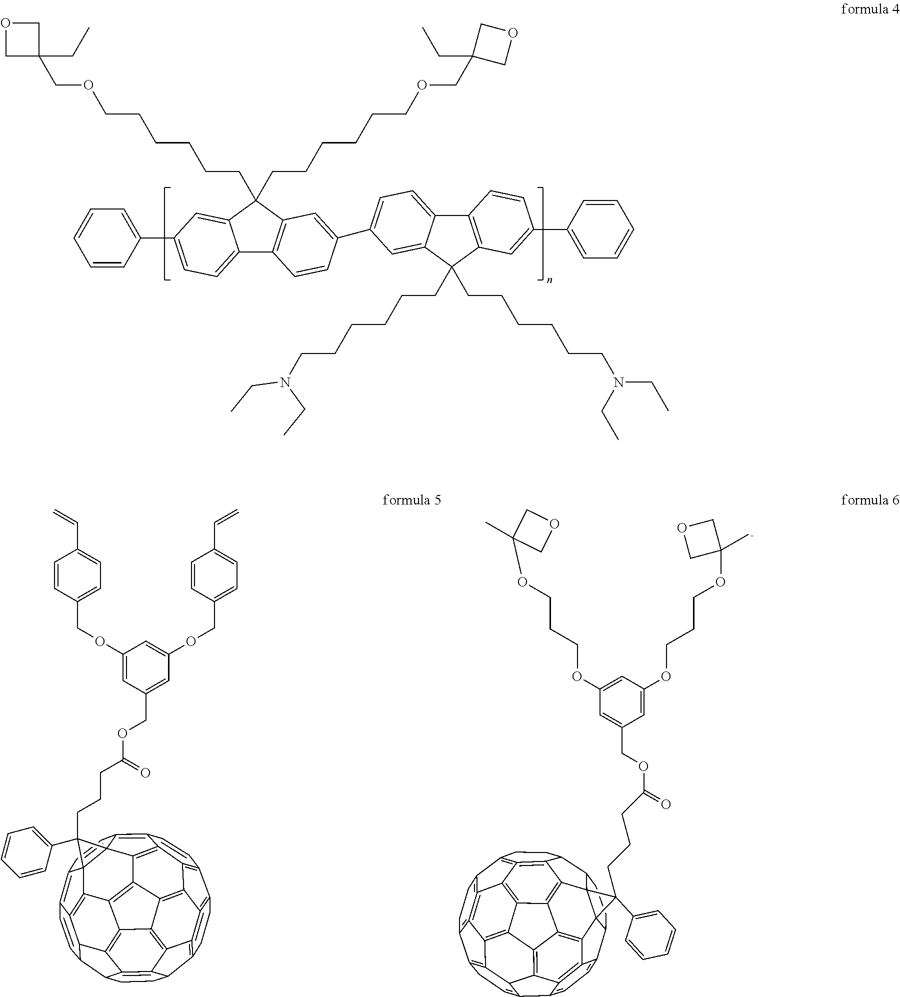

9. The perovskite light-emitting device according to claim 1, further comprising a second charge transport layer disposed between the light-emitting layer and the second charge injection layer.

10. A fabricating method of a perovskite light-emitting device, comprising:
forming a first charge injection layer on a first electrode layer;
forming a first charge transport layer on the first charge injection layer, wherein a material of the first charge transport layer comprises a crosslinkable material;
forming a light-emitting layer on the first charge transport layer, wherein a material of the light-emitting layer comprises a light-emitting material having a perovskite crystal structure;
forming a second charge injection layer on the light-emitting layer; and
forming a second electrode layer on the second charge injection layer.

11. The fabricating method of the perovskite light-emitting device according to claim 10, wherein the light-emitting material having the perovskite crystal structure has a structure represented by the following formula (I):
ABX₃ (I)
wherein A is an organic ammonium cation; B is a group IV metal cation or a transition metal cation; X₃ are a combination of single type halogen-containing anion or a combination of multiple type halogen-containing anion.

12. The fabricating method of the perovskite light-emitting device according to claim 11, wherein the organic ammonium cation is a C₁ to C₅₀ alkyl ammonium cation or an aromatic ammonium cation; the group IV metal cation is Pb²⁺, Ge²⁺, or Sn²⁺; the transition metal cation is Cu²⁺, Ni²⁺, Co²⁺, Fe²⁺, Mn²⁺, or Eu²⁺; the single type halogen-containing anion is Cl⁻, Br⁻, or I⁻; the combination of multiple type halogen-containing anion has the following general formula: —Cl⁻ₓBr⁻_{y}I⁻_{z}, wherein x+y+z=3.

13. The fabricating method of the perovskite light-emitting device according to claim 11, wherein the light-emitting material having the perovskite crystal structure is CH₃NH3PbBr₃, CH₃NH₃PbBr₂I, CH₃NH₃PbCl₃, or CH₃NH₃PbBrCl₂.

14. The fabricating method of the perovskite light-emitting device according to claim 10, wherein the first charge injection layer is an hole injection layer, the first charge transport layer is an hole transport layer, and the second charge injection layer is an electron injection layer.

15. The fabricating method of the perovskite light-emitting device according to claim 14, wherein the crosslinkable material comprises a compound represented by the following formula 1, a compound represented by the following formula 2, or a compound represented by the following formula 3:

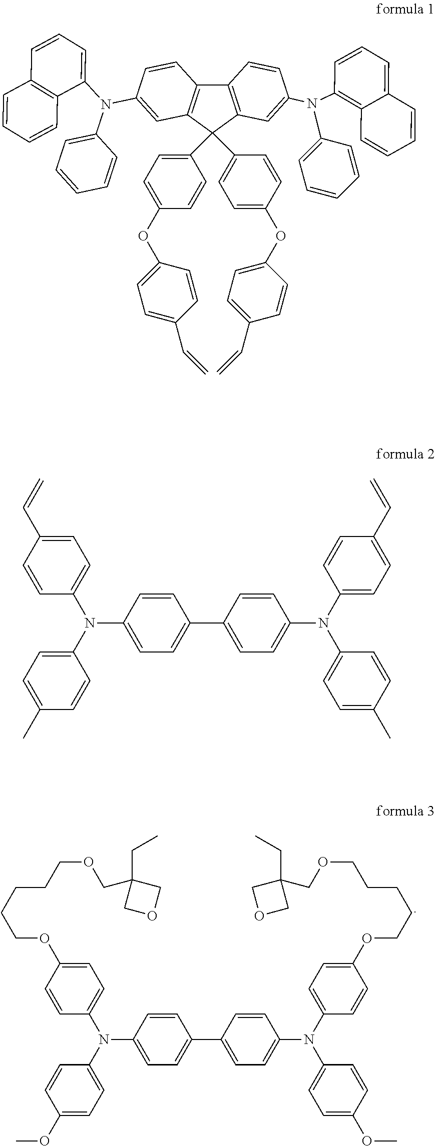 [SMILES: C=Cc1ccc(Oc2ccc(C3(c4ccc(Oc5ccc(C=C)cc5)cc4)c4cc(N(c5ccccc5)c5cccc6ccccc56)ccc4-c4ccc(N(c5ccccc5)c5cccc6ccccc56)cc43)cc2)cc1 ; C=Cc1ccc(N(c2ccc(C)cc2)c2ccc(-c3ccc(N(c4ccc(C)cc4)c4ccc(C=C)cc4)cc3)cc2)cc1 ; CCC1(COCCCCCOc2ccc(N(c3ccc(OC)cc3)c3ccc(-c4ccc(N(c5ccc(OC)cc5)c5ccc(OCCCCCOCC6(CC)COC6)cc5)cc4)cc3)cc2)COC1]

16. The fabricating method of the perovskite light-emitting device according to claim 10, wherein the first charge injection layer is an electron injection layer, the first charge transport layer is an electron transport layer, and the second charge injection layer is an hole injection layer.

17. The fabricating method of the perovskite light-emitting device according to claim 16, wherein the crosslinkable material comprises a compound represented by the following formula 4, a compound represented by the following formula 5, or a compound represented by the following formula 6:

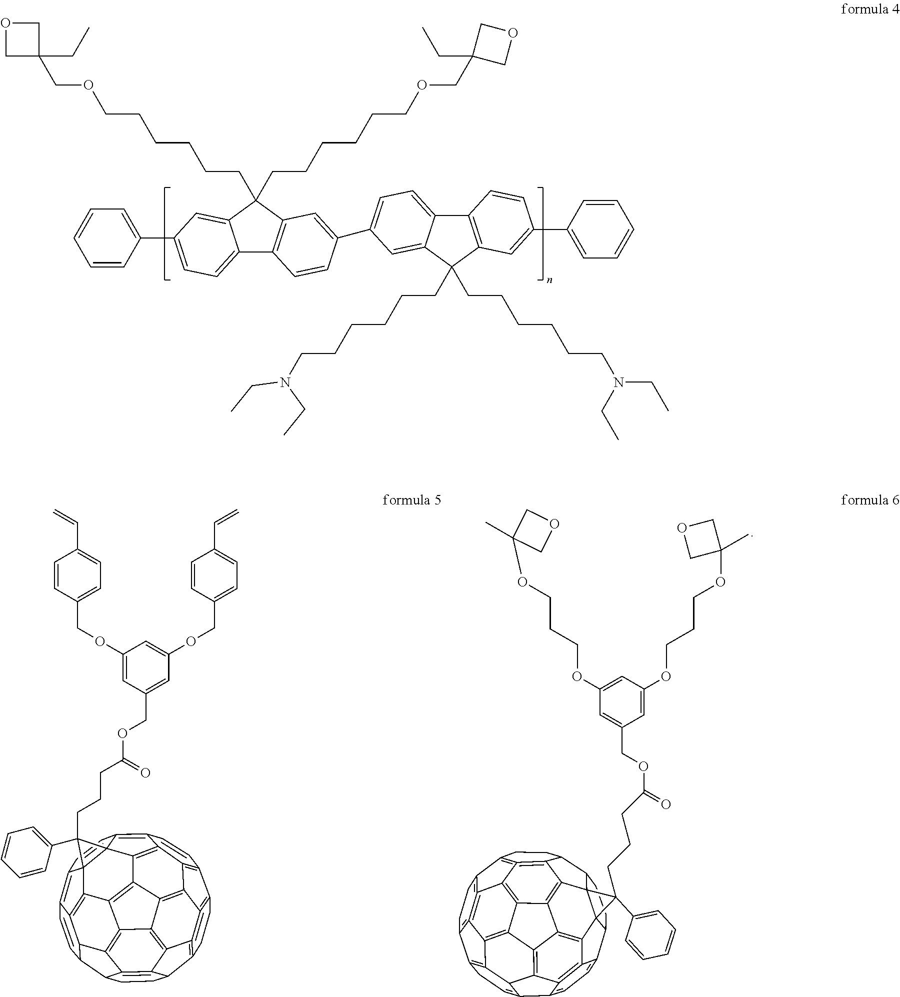

18. The fabricating method of the perovskite light-emitting device according to claim 10, further comprising forming a second charge transport layer on the light-emitting layer before forming the second charge injection layer on the light-emitting layer.

19. The fabricating method of the perovskite light-emitting device according to claim 18, wherein a method of forming the first charge injection layer, the first charge transport layer, the light-emitting layer, the second charge transport layer, and the second charge injection layer is a solution process.

20. The fabricating method of the perovskite light-emitting device according to claim 19, wherein in the solution process of forming the first charge transport layer, a solution containing the crosslinkable material is used, wherein a concentration of the crosslinkable material is 0.01 wt % to 100 wt %.
